(19) United States
(12) Patent Application Publication
(10) Pub. No.: US 2025/0246496 A1
(43) Pub. Date: Jul. 31, 2025

(54) SEMICONDUCTOR MODULE

(71) Applicant: FUJI ELECTRIC CO., LTD., Kawasaki-shi (JP)

(72) Inventor: Ryu ARAKI, Matsumoto-city (JP)

(73) Assignee: FUJI ELECTRIC CO., LTD., Kawasaki-shi (JP)

(21) Appl. No.: 18/961,014

(22) Filed: Nov. 26, 2024

(30) Foreign Application Priority Data
Jan. 31, 2024 (JP) 2024-012501

(51) Int. Cl. H01L 23/34; H01L 23/62

(52) U.S. Cl. CPC H01L 23/34; H01L 23/62

(57) ABSTRACT

A semiconductor module includes a metal plate, a plurality of switching devices joined to one surface of the metal plate, a thermal fuse joined to the surface of the metal plate, and an external terminal electrically connected to the plurality of the switching devices by being joined to the thermal fuse.

### CROSS REFERENCE TO RELATED APPLICATION

This Application is based on, and claims priority from, Japanese Patent Application No. 2024-012501, filed Jan. 31, 2024, the entire content of which is incorporated herein by reference.

### BACKGROUND OF THE INVENTION

### Field of the Invention

The present disclosure relates to a semiconductor module.

### Description of Related Art

A semiconductor module, exemplified by a power semiconductor module, includes, for example, switching devices such as an IGBT (Insulated Gate Bipolar Transistor) as disclosed in patent documents such as Japanese Patent Application Laid-Open Publication No. 2014-99547, Japanese Patent Application Laid-Open Publication No. 2005-175506, Japanese Patent Application Laid-Open Publication No. 2011-216755, Japanese Patent Application Laid-Open Publication No. H5-135850, Japanese Patent Application Laid-Open Publication No. 2018-81947, and Japanese Patent Application Laid-Open Publication No. 2005-123516.

Conventionally, a fail-safe measure is taken in which the operation of a semiconductor module is stopped when a temperature detected by a temperature sensor provided within the module has reached a predetermined temperature or higher. Another measure is to dispose a current fuse in a main current path of the module.

However, in a power semiconductor module in which a large current flows, it is difficult to achieve a balance with performance if a current fuse is used. Therefore, there is room for improvement from the viewpoint of achieving both fail-safe measures and conduction performance at the time of a system abnormality.

### SUMMARY OF THE INVENTION

In view of the above circumstances, an object of one aspect of the present disclosure is to appropriately prevent excessive temperature rise of a semiconductor module.

In order to solve the above problem, a semiconductor module according to a preferred embodiment of the present disclosure includes a metal plate, a plurality of switching devices joined to one surface of the metal plate, a thermal fuse joined to the one surface of the metal plate, and an external terminal electrically connected to the plurality of the switching devices by being joined to the thermal fuse.

### BRIEF DESCRIPTION OF THE DRAWINGS

FIG. 1 is a plan view of a semiconductor module according to an embodiment.

FIG. 2 is a cross-sectional view of a portion of the semiconductor module according to the embodiment.

FIG. 3 is a plan view for explaining an arrangement of a thermal fuse.

FIG. 4 is a circuit diagram showing an application example of the semiconductor module according to the embodiment.

### DESCRIPTION OF THE EMBODIMENTS

In the following, an embodiment according to the present disclosure will be described with reference to the drawings. In the drawings, the dimensions and scales of the respective parts differ appropriately from those of actual parts. Furthermore, the embodiments described below are preferred specific examples of the present disclosure. For this reason, various technically preferable limitations are attached to the following embodiment. However, the scope of the present disclosure is not limited to these forms unless specifically stated to so limit the present disclosure in the following description.

### 1. Embodiment

### 1-1. Overall Configuration of Semiconductor Module

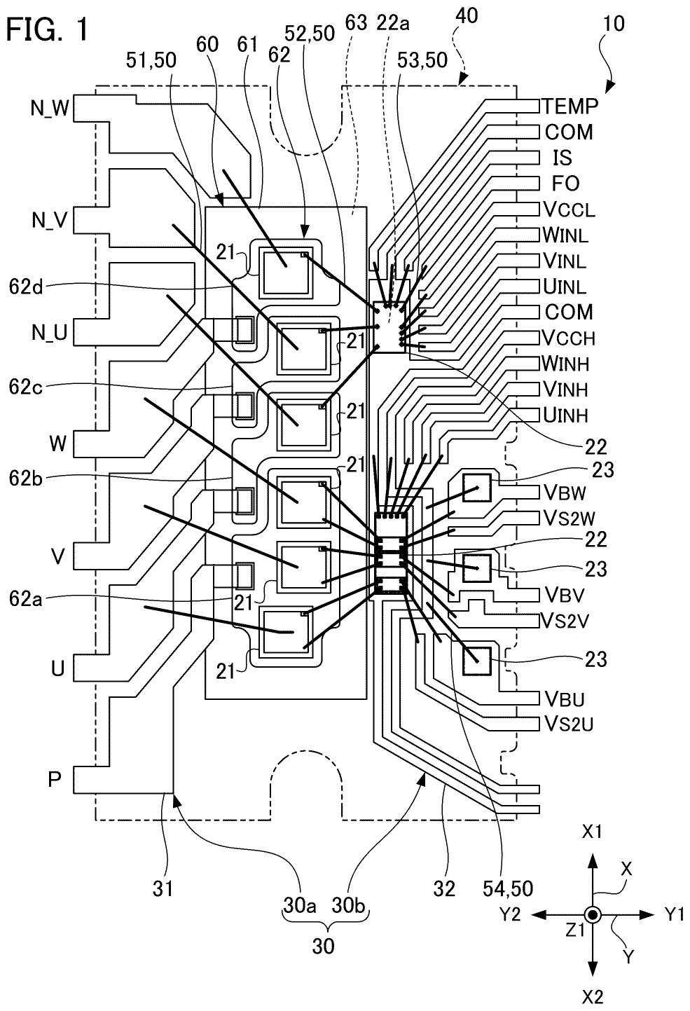

FIG. 1 is a plan view of a semiconductor module 10 according to an embodiment. The semiconductor module 10 is a power module such as an IGBT (Insulated Gate Bipolar Transistor) module. In the embodiment illustrated in FIG. 1, the semiconductor module 10 is an IPM (Intelligent Power Module) incorporating an inverter bridge circuit and a control circuit, and is used for power control in a device such as an inverter or a rectifier mounted for example on an air conditioner, a railroad vehicle, an automobile, or a device such as a household electric machine.

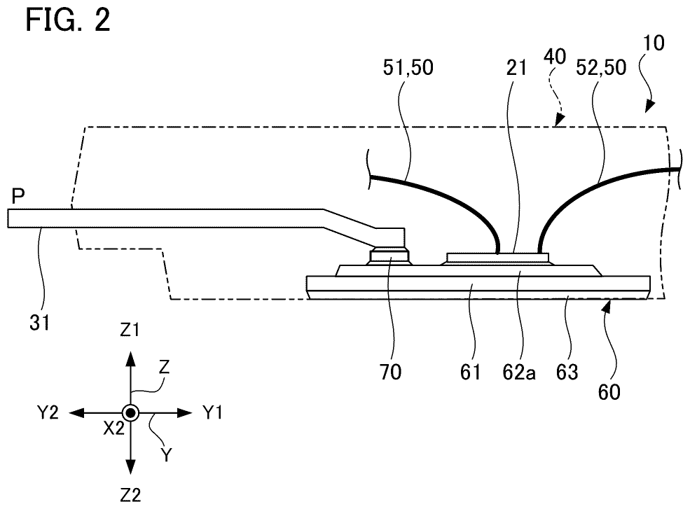

As shown in FIG. 1, the semiconductor module 10 includes a plurality of switching devices 21, a plurality of control elements 22, a plurality of diodes 23, a lead group 30, a sealing resin 40, a wire group 50, an insulating substrate 60, and a thermal fuse 70. In FIG. 2, for convenience of explanation, only the outer edge of the sealing resin 40 is schematically shown by a two-dot chain line.

An outline of each part of the semiconductor module 10 will be now described with reference to FIG. 1. For convenience, the following description will be made using an X-axis, a Y-axis, and a Z-axis orthogonal to each other as appropriate. The Z-axis is parallel to a thickness direction of the semiconductor module 10. In the following, one direction along the X axis is an X1 direction, and a direction opposite to the X1 direction is an X2 direction. One direction along the Y-axis is a Y1 direction, and a direction opposite to the Y1 direction is a Y2 direction. One direction along the Z-axis is a Z1 direction, and a direction opposite to the Z1 direction is a Z2 direction. The relationship between these directions and the vertical direction is not particularly limited, and may be freely selected.

One each of the plurality of the switching devices 21 is a semiconductor switching device, such as an IGBT (Insulated Gate Bipolar Transistor) or a power MOSFET (metal-oxide-semiconductor field-effect transistor). In the embodiment illustrated in FIG. 1, each switching device 21 is, for example, an RC (Reverse-Conducting)-IGBT, and further includes a diode, such as an FWD (Freewheeling Diode).

On the back surface of each one of the switching devices 21, there is provided a drain electrode or a collector electrode, which is an input electrode of the switching device, and there is further provided a cathode electrode, which is an output electrode of the diode. The cathode electrode is to be electrically connected to the input electrode of the switching device. On the other hand, on the front surface of each one of the switching devices 21, there are provided a source electrode or an emitter electrode, which is an output electrode of each switching device, and a gate electrode, which is a control electrode, and there is further provided an anode electrode which is an input electrode of the diode. The anode electrode is to be electrically connected to the output electrode.

In the example shown in FIG. 1, there are six switching devices 21. The six switching devices 21 form three half-bridge circuits of the U phase, the V phase, and the W phase. Here, among the six switching devices 21, three switching devices 21 on the lower side (X2 direction) in FIG. 1 are on the high potential side, and the remaining three switching devices 21 on the upper side (X1 direction) in FIG. 1 are on the low potential side.

The number of the plurality of the switching devices 21 is not limited to the example shown in FIG. 1, and this may be feely selected. In addition, a diode, such as an FWD (Freewheeling Diode), may be provided separately from the plurality of the switching devices 21. In this case, for example, an output electrode of each one of the switching devices 21 is electrically connected to an input electrode of a corresponding diode via a bonding wire.

Each of the plurality of the control elements 22 is an electronic component, such as an IC (Integrated Circuit), for controlling driving of the switching devices 21. In the example shown in FIG. 1, there are two control elements 22. Of the two control elements 22, a control element 22 on the lower side (X2 direction) in FIG. 1 corresponds to the three switching devices 21 on the high potential side, and the other control element 22 on the upper side (X1 direction) in FIG. 1 corresponds to the three switching devices 21 on the low potential side. Each of the two control elements 22 is electrically connected to the respective control electrodes of the corresponding three switching devices 21 via the bonding wires 52 in the wire group 50, and controls the driving of the respective three switching devices 21.

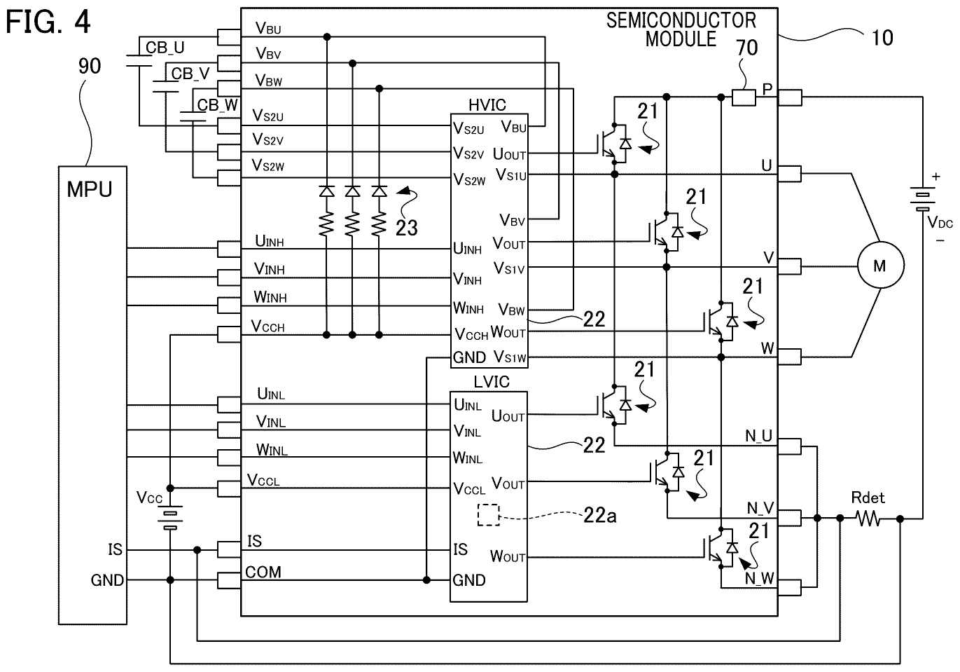

In the present embodiment, as will be described in detail later with reference to FIG. 4, of the two control elements 22, a control element 22 corresponding to the three switching devices 21 on the low potential side has a temperature sensor 22a. This control element 22 cuts off flow of current to the three switching devices 21 on the low potential side when a temperature detected by the temperature sensor 22a has reached a predetermined value.

Each of the plurality of the diodes 23 is a diode, such as a BSD (Bootstrap Diode). In the example shown in FIG. 1, there are three diodes 23, and the three diodes 23 are electrically connected to the front surface of the control element 22 on the high potential side via the bonding wires 54 in the wire group 50.

The insulating substrate 60 is, for example, a DCB (Direct Copper Bonding) substrate or a DBA (Direct Bonded Aluminum) substrate for mounting the plurality of the switching devices 21. The insulating substrate 60 includes an insulating plate 61, a conductor pattern 62 joined to a front surface of the insulating plate 61, and a conductor plate 63 joined to a back surface of the insulating plate 61.

The insulating plate 61 is a plate-shaped member made from a resin composition. The resin composition includes, for example, a resin, such as an epoxy resin, and an inorganic filler, such as silicon oxide (SiO₂) or boron nitride (BN). The conductor pattern 62 is made from a metal such as copper or aluminum, and includes a plurality of conductor plates separated from each other. In the embodiment illustrated in FIG. 1, the conductor pattern 62 includes metal plates 62a, 62b, 62c, 62d in the form of the plurality of the conductor plates. The back surfaces of the three switching devices 21 on the high potential side are joined by soldering or a similar method on a surface of the metal plate 62a facing in the Z1 direction. On each one of the metal plates 62b, 62c, 62d, the back surface of a corresponding switching device 21 on the low potential side is joined by soldering or a similar method. The conductor plate 63 is made from a metal, such as copper or aluminum, and has a function of dissipating heat from the switching devices 21.

With the use of the insulating substrate 60, the metal plates 62a, 62b, 62c, 62d can be easily installed at desired positions when the semiconductor module 10 is manufactured. Furthermore, since the insulating plate 61 is formed from a resin composition, the insulating plate 61 is more likely to be damaged due to excessive temperature rise than in a configuration in which the insulating plate 61 is formed from ceramics. Therefore, the effect of preventing the excessive temperature rise of the semiconductor module 10, as described later, is remarkable. It is to be noted that the shape of the conductor patterns 62 shown in FIG. 1 is a mere example, and this is not limited thereto. In addition, the insulating plate 61 is not limited to being composed of a resin composition, and it may be composed of ceramics such as aluminum nitride, aluminum oxide, or silicon nitride.

The lead group 30 is a set of a plurality of leads for electrically connecting each of the plurality of the switching devices 21, the plurality of the control elements 22, and the plurality of the diodes 23 to a substrate (not shown) for mounting the semiconductor module 10. The lead group 30 is made from, for example, a metal such as copper, a copper alloy, aluminum, an aluminum alloy, or an iron alloy, and it is obtained by processing a lead frame.

The lead group 30 includes a plurality of external terminals 31 for power supply and a plurality of external terminals 32 for control.

Each of the plurality of the external terminals 31 is disposed from inside to outside of the sealing resin 40, and is electrically connected to the main current paths of the switching devices 21. In the example illustrated in FIG. 1, there are seven external terminals 31. The seven external terminals 31 include output terminals U, V, and W, a positive DC terminal P, and negative DC terminals N_U, N_V, and N_W of the three half-bridge circuits described above.

An external terminal 31 serving as the positive DC terminal P is joined to the metal plate 62a of the insulating substrate 60 by soldering or a similar method via the thermal fuse 70. An external terminal 31 serving as the output terminal U is joined to the metal plate 62b of the insulating substrate 60 by soldering or a similar method. An external terminal 31 serving as the output terminal Vis joined to the metal plate 62c of the insulating substrate 60 by soldering or a similar method. An external terminal 31 serving as the output terminal W is joined to the metal plate 62d of the insulating substrate 60 by soldering or a similar method. The thermal fuse 70 will be described later with reference to FIG. 2.

Here, three external terminals 31 serving as the output terminals U, V, and W correspond to the three switching devices 21 on the metal plate 62a described above, and are electrically connected to the output electrodes of the respective switching devices 21 via the bonding wires 51 in the wire group 50. Furthermore, the negative DC terminals N_U, N_V, and N_W correspond to the three switching devices 21 on the metal plate 62b, 62c, 62d described above, and are electrically connected to the output electrodes of the respective switching devices 21 via the bonding wires 51 of the wire group 50.

Each of the plurality of the external terminals 32 is disposed from inside to outside of the sealing resin 40, and is electrically connected to one of the control elements 22 or one of the diodes 23. In the example shown in FIG. 1, there are 21 external terminals 32, and the 21 external terminals 32 include gate power terminals V_{BU}, V_{BV}, V_{BW}, reference potential terminals V_{S2U}, V_{S2V}, V_{S2W}, signal input terminals U_{INH}, V_{INH}, W_{INH}, signal power supply terminals V_{CCH}, two common terminals COM, signal input terminals U_{INL}, V_{INL}, W_{INL}, signal power supply terminals V_{CCL}, current detecting terminals IS, two NC terminals, and two dummy terminals. Of the two dummy terminals, one dummy terminal is electrically connected to the power supply terminal V_{CCH}, and the other dummy terminal is electrically connected to the common terminal COM. In addition, the NC terminals are used for outputting a signal indicating a value detected by the temperature sensor 22a.

The back surfaces of the two control elements 22 are joined to the two common terminals COM via an insulating or conductive adhesive, or other suitable materials. The back surface of each the diodes 23 is joined to the gate power terminals V_{BU}, V_{BV}, and V_{BW}, respectively, via a conductive adhesive or other similar materials. The 21 external terminals 32 are electrically connected to the front surfaces of the two control elements 22 via the bonding wires 53 in the wire group 50 appropriately.

The sealing resin 40 seals the plurality of the switching devices 21, the plurality of the control elements 22, the plurality of the diodes 23, and a portion of the lead group 30. Although not shown, a heat dissipation member such as a heat dissipation fin is joined to the back surface of the sealing resin 40 by screwing or a similar method. The heat dissipation member dissipates heat from the plurality of the switching devices 21 to the outside.

The sealing resin 40 is formed from a resin composition including a resin, such as a thermosetting resin (e.g., an epoxy resin). The resin composition preferably contains an inorganic filler from the viewpoint of enhancing thermal conductivity. Examples of the inorganic filler include silica (SiO₂) fillers. The surface of the inorganic filler is subjected to a surface treatment such as a coupling treatment, as necessary.

Although not shown, the sealing resin 40 includes, for example, a frame-shaped first portion formed by insert molding, with a lead frame including the lead group 30 as the insert, and a second portion filled inside the first portion. In manufacturing the semiconductor module 10, for example, the insulating substrate 60 is disposed inside the first portion after the first portion is molded, with the plurality of the switching devices 21 mounted on the insulating substrate 60, and then the second portion is formed after the wire group 50 is formed.

### 1-2. Thermal Fuse

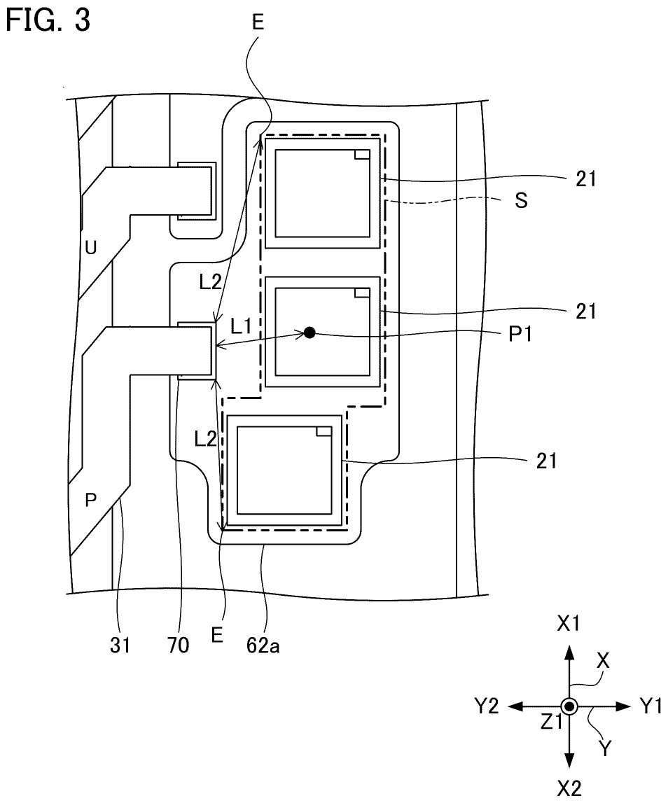

FIG. 2 is a cross-sectional view of a portion of the semiconductor module 10 according to the embodiment. FIG. 3 is a plan view for explaining an arrangement of the thermal fuse 70. In an example shown in FIG. 2, of the plurality of the external terminals 31 of the semiconductor module 10, the external terminal 31 serving as the positive DC terminal P is connected to the insulating substrate 60. In FIG. 2, the outer edge of the sealing resin 40 is schematically indicated by a two-dot chain line for simplicity. FIG. 3 shows a configuration of the semiconductor module 10 on the metal plate 62a. The wire group 50 is not shown for convenience of explanation.

Of the plurality of the external terminals 31, the external terminal 31 used as the positive DC terminal P is electrically connected to the metal plate 62a of the insulating substrate 60 via the thermal fuse 70 as shown in FIG. 2. Furthermore, the sealing resin 40 covers the plurality of the switching devices 21, the thermal fuse 70, the metal plate 62a, and a portion of the external terminal 31 (positive DC terminal P).

In the example shown in FIG. 2, the thermal fuse 70 is plate-shaped with a thickness direction along the Z-axis. A surface of the thermal fuse 70 facing in the Z1 direction is joined to a surface of the external terminal 31 used as the positive DC terminal P facing in the Z2 direction, by way of a conductive bonding material, such as solder A. The other surface of the thermal fuse 70 facing in the Z2 direction is joined to a surface of the metal plate 62a facing in the Z1 direction by way of a conductive bonding material, such as solder. As a result, the thermal fuse 70 is joined to one surface of the metal plate 62a. The external terminal 31 used as the positive DC terminal P is electrically connected to the plurality of the switching devices 21 on the high potential side by being joined to the thermal fuse 70.

The thermal fuse 70 is an overcurrent protection element that cuts off electrical conduction when a predetermined temperature is reached. Accordingly, the thermal fuse 70 protects the plurality of the switching devices 21 on the high potential side from overheating.

As described above, since the thermal fuse 70 is joined to the same metal plate 62a to which the plurality of the switching devices 21 on the high potential side is connected, the thermal fuse 70 can activate with high precision according to the temperature of these switching devices 21. In addition, since the external terminal 31 (positive DC terminal P) and the plurality of the switching devices 21 on the high potential side are electrically connected via the thermal fuse 70 and the metal plate 62a, the operation of the plurality of the switching devices 21 can be stopped collectively by the operation of the thermal fuse 70. Moreover, since the positional relationship between the metal plate 62a and the external terminal 31 (positive DC terminal P) is fixed by the sealing resin 40, the external terminal 31 (positive DC terminal P) and the metal plate 62a can be stably insulated from each other after the thermal fuse 70 activates. Thus, it is possible to suitably prevent excessive temperature rise of the semiconductor module 10.

The functioning temperature of the thermal fuse 70 is less than a thermal decomposition temperature of the sealing resin 40. As a result, the thermal fuse 70 can activate before the sealing resin 40 is thermally decomposed. Therefore, it is possible to prevent unintentional electrical conduction due to carbonization after the sealing resin 40 is thermally decomposed. Consequently, even after the thermal fuse 70 activates, the sealing resin 40 not only maintains the fixed positional relationship between the metal plate 62a and the external terminal 31 (positive DC terminal P), but also effectively maintains electrical insulation.

From the same viewpoint, the functioning temperature of the thermal fuse 70 is preferably lower than the thermal decomposition temperature of the resin composition of the insulating plate 61. In this way, the thermal fuse can activate before the resin composition of the insulating plate 61 is thermally decomposed. With this configuration, it is possible to prevent unintentional electrical conduction due to carbonization resulting from thermal decomposition of the insulating plate 61. A specific functioning temperature of the thermal fuse 70 is determined based on type of resin used for the sealing resin 40 and the insulating plate 61, and it is not particularly limited. For example, the functioning temperature may be within a range of 180° to 220°.

As shown in FIG. 3, the distance L1 between a center P1 of a set S of the plurality of switching devices 21 on the high potential side and the thermal fuse 70, is shorter than the distance L2 between an end E of the set S in the longitudinal direction and the thermal fuse 70. Thus, the variation in distance between the switching device 21 on the high potential side and the thermal fuse 70, depending on a different switching device 21, is reduced. Since the variation in distance is reduced, the thermal fuse 70 can activate with high precision in response to the temperature rise of each of the plurality of the switching devices 21 on the high potential side. In the present embodiment, the plurality of the switching devices 21 on the high potential side is arranged in a direction along the X-axis, and the longitudinal direction of the set S is the direction along the X-axis.

The plurality of the switching devices 21 corresponds to different phases, and is controlled to be driven independently of each other. By activating the thermal fuse 70, an excessive temperature rise of the plurality of the semiconductor modules 10, differing in phase from each other, is effectively prevented.

A one-shot thermal fuse or a resettable thermal fuse can be used in the form of the thermal fuse 70.

A one-shot thermal fuse has a conductor that melts and thereby cuts off electrical conduction when the functioning temperature is reached. When the thermal fuse 70 is a one-shot type, unintentional electrical conduction can be more reliably prevented after the thermal fuse 70 is activated.

In contrast, a resettable thermal fuse is an element that cuts off electrical conduction when a predetermined temperature is reached, but restores electrical conduction when the temperature falls below the predetermined temperature even after the predetermined temperature is reached. In the case of a resettable thermal fuse 70, if there is no abnormality in each part of the semiconductor module 10 after the thermal fuse 70 activates, the semiconductor module 10 can be restored without replacing the thermal fuse 70.

Examples of the resettable thermal fuse include a poly switch. The poly switch includes a molded body including conductive particles, such as carbon or nickel, and a resin, and restricts electrical conduction by reducing contact between the conductive particles by way of expansion of the resin with an increase in temperature. Even after the predetermined temperature is reached, the poly switch returns to its original state as the resin shrinks when the poly switch cools. It is to be noted that the resettable thermal fuse is not limited to a poly switch, and may be, for example, a device that uses a material such as a conductive metal oxide, such as (V_{1-X}Cr_{X})₂O₃, for which resistivity increases as a result of a phase transition at a predetermined temperature or higher.

### 1-3. Application Example of Semiconductor Module

FIG. 4 is a circuit diagram illustrating an application example of the semiconductor module 10 according to the embodiment. In the embodiment illustrated in FIG. 4, a motor M, a DC power supply V_{DC}, a current detecting resistor R_{det}, power supply capacitors CB_U, CB_V, and CB_W, a signal power supply V_{CC}, and a controller 90 are connected to the semiconductor module 10.

The motor M is a three-phase motor and is connected to the output terminals U, V, W of the three half-bridge circuits described above. The positive electrode of the DC power supply V_{DC} is connected to the positive DC terminal P of the three half-bridge circuits. The negative electrode of the DC power supply V_{DC} is connected to each of the negative DC terminals N_U, N_V, and N_W of the three half-bridge circuits via the current detecting resistor R_{det}. As described above, the semiconductor module 10 receives DC power from the DC power supply V_{DC} via the positive DC terminal P and the negative DC terminals N_U, N_V, and N_W, and supplies the power to the motor M via the output terminals U, V, and W.

The power supply capacitors CB_U, CB_V, and CB_W are used as gate-drive power supplies for the three switching devices 21 at the high potential side. Of a pair of terminals of the power supply capacitor CB_U, one terminal is connected to a gate power terminal V_{BU}, and the other terminal is connected to a reference potential terminal V_{S2U}. Similarly, of a pair of terminals of the power supply capacitor CB_V, one terminal is connected to the gate power terminal V_{BV}, and the other terminal is connected to the reference potential terminal V_{S2V}. Of a pair of terminals of the power supply capacitor CB_W, one terminal is connected to the gate power terminal V_{BW}, and the other terminal is connected to the reference potential terminal V_{S2W}.

The positive electrode of the signal power supply V_{CC} is connected to each of the signal power supply terminal V_{CCH} and the signal power supply terminal V_{CCL}. The negative electrode of the signal power supply V_{CC} is connected to each of the ground terminal (GND) of the controller 90 and the common terminal COM. Each of the gate power terminal V_{BU}, V_{BV}, V_{BW} is connected to the signal power supply terminal V_{CCH} via a corresponding diode 23, which is a BSD, the anode of which is connected to the signal power supply terminal V_{CCH}. With this configuration, each of the power supply capacitors CB_U, CB_V, and CB_W is charged by the electric power from the signal power supply V_{CC}.

The controller 90 is an integrated arithmetic unit (MPU: Microprocessor Unit) for PWM (pulse width modulation) control. The controller 90 is connected to the signal input terminals U_{INH}, V_{INH}, W_{INH}, the common terminal COM, the signal input terminals U_{INL}, V_{INL}, W_{INL}, and the current detecting terminal IS.

The controller 90 outputs a PWM signal input to each of the signal input terminals U_{INH}, V_{INH}, W_{INH} and the signal input terminals U_{INL}, V_{INL}, W_{INL}. The PWM signal input to each of the signal input terminals U_{INH}, V_{INH}, W_{INH} is input to the control element 22 on the high potential side. The PWM signal input to each of the signal input terminals U_{INL}, V_{INL}, W_{INL} is input to the control element 22 on the low potential side. Based on the PWM signal input, each of the control elements 22 outputs a signal for changing the gate potentials of the corresponding three switching devices 21 from output terminals U_{OUT}, V_{OUT}, W_{OUT}. Accordingly, the switching device 21 is switched on and off based on the PWM signal from the controller 90.

The semiconductor module 10 has a function of detecting a current flowing through each phase of the three half-bridge circuits based on the resistance of the current detecting resistor R_{det}, to protect the semiconductor module 10 from damage when an overcurrent is generated. A current level signal that corresponds to the change in the resistance value of the current detecting resistor R_{det} is input to the control element 22 on the low potential side via the current detecting terminal IS, and is input to the controller 90. The control element 22 on the low potential side determines whether an overcurrent is generated based on a result of comparison between the current level signal and a reference value, and when an overcurrent is generated, cuts off the current of the switching devices 21 on the low potential side. In addition, the controller 90 determines whether an overcurrent is generated based on a comparison between the current level signal and the reference value, and when an overcurrent is generated, cuts off the current of the switching devices 21 on the high potential side.

Furthermore, in the semiconductor module 10, as described above, the thermal fuse 70 is interposed between the positive DC terminal P and the three switching devices 21 on the high potential side, and when the functioning temperature is reached, the thermal fuse 70 collectively cuts off the current of the switching devices 21 on the high potential side.

The control element 22 on the low potential side collectively cuts off the current of the switching devices 21 on the high potential side as well when a temperature detected by the temperature sensor 22a reaches the predetermined temperature.

Specifically, when a temperature detected by the temperature sensor 22a reaches a predetermined value, the control element 22 on the low potential side cuts off a flow of current to the plurality of the switching devices 21 on the low potential side. In addition, the control element 22 on the low potential side shuts down the system by outputting an FO alarm signal to the controller 90. The predetermined temperature is lower than the functioning temperature of the thermal fuse 70. Accordingly, when the control element 22 can operate normally, it is possible to prevent an excessive temperature rise of the semiconductor module 10 without activating the thermal fuse 70. Furthermore, even if the control element 22 cannot operate normally due to some problem, an excessive temperature rise of the semiconductor module 10 can be prevented by the activation of the thermal fuse 70.

### 2. Modifications

The present disclosure is not limited to the above-described embodiments, and various modifications described below are possible. Furthermore, the embodiment and any one or more modifications may be combined as appropriate.

### 2-1. Modification 1

In the above-described embodiment, the thermal fuse 70 is disposed on the metal plate 62a. However, the present disclosure is not limited thereto. For example, the thermal fuse 70 may be joined to one or more of the metal plates 62b, 62c, 62d. In other words, the external terminal 31 using the thermal fuse 70 is not limited to the positive DC terminal P. For example, any one or more of the external terminals 31 used as the output terminals U, V, and W may use the thermal fuse 70.

The number of the thermal fuses 70 is not limited to one, and it may be two or more.

### 2-2. Modification 2

In the above-described embodiment, the insulating plate 61 and the conductor plate 63 are used, but the present disclosure is not limited thereto. For example, the insulating plate 61 and the conductor plate 63 may be omitted. In this case, for example, the thickness of the conductor pattern 62 may be greater than that shown in the above figures.

### 2-3. Modification 3

In the above-described embodiment, the temperature sensor 22a is disposed within the control element 22. However, the temperature sensor 22a may be configured separately from the control element 22. The temperature sensor 22a may be arranged in the semiconductor module 10, for example, on the insulating substrate 60. The temperature sensor 22a is not limited to an IC temperature sensor, and it may be a temperature detecting device, such as a thermocouple, an RTD (Resistance Temperature Detector), a thermistor, or a similar device. In addition, the number of the temperature sensors 22a may be two or more. For example, the temperature sensor 22a may be incorporated in each one of the two control elements 22, or the temperature sensor 22a may be disposed at more than one position on the insulating substrate 60.

A configuration of using the temperature sensor 22a to cut off the current of the switching devices 21 may be provided as needed, or it may be omitted.

### 3. Appendices

From the above embodiments or modifications, for example, the following aspects are derivable.

Appendix 1: A first aspect which is a preferred example of the semiconductor module of the present disclosure includes a metal plate, a plurality of switching devices joined to one surface of the metal plate, a thermal fuse joined to the one surface of the metal plate, and an external terminal electrically connected to the plurality of the switching devices by being joined to the thermal fuse.

In the above aspect, since the thermal fuse is joined to the same metal plate as the plurality of the switching devices, the thermal fuse can activate with high precision in accordance with the temperature of these switching devices. Furthermore, since the external terminal is electrically connected to the plurality of the switching devices via the thermal fuse and the metal plate, the operation of the plurality of the switching devices can be collectively cut off by the activation of the thermal fuse. Therefore, it is possible to suitably prevent excessive temperature rise of the semiconductor module.

Appendix 2: In a second aspect, which is a preferred example of the first aspect, the semiconductor device further includes an insulating substrate for mounting the plurality of the switching devices, wherein the insulating substrate includes an insulating plate and a conductor pattern disposed on one surface of the insulating plate, and the conductor pattern includes the metal plate. According to the above aspect, the metal plate can be easily installed at a desired position when a semiconductor module is manufactured.

Appendix 3: In a third aspect, which is a preferred example of the second aspect, the insulating plate is made from a resin composition. In the above aspect, the insulating plate is more likely to be damaged due to excessive temperature rise than in a configuration in which the insulating plate is made of ceramic. Therefore, the effect of preventing excessive temperature rise of the semiconductor module according to the third aspect is remarkable.

Appendix 4: In a fourth aspect, which is a preferred example of the third aspect, a functioning temperature of the thermal fuse is less than a thermal decomposition temperature of the resin composition. In the above aspect, the thermal fuse can activate before the resin composition of the insulating plate is thermally decomposed. Therefore, it is possible to prevent unintentional conduction, which could occur due to carbonization after the insulating plate undergoes thermal decomposition.

Appendix 5: In a fifth aspect, which is the preferred example of any of the first to fourth aspects, a distance between the thermal fuse and a center of a set of the plurality of the switching devices is shorter than a distance between the thermal fuse and an end of the set of the plurality of the switching devices in a longitudinal direction. In the above aspect, the variation in distance between the switching device and the thermal fuse, depending on different switching devices, can be reduced. Therefore, the thermal fuse can activate with high precision in accordance with the temperature rise of each of the switching devices. Furthermore, it is possible to prevent delay in cut offs in an event of a temperature rise.

Appendix 6: In a sixth aspect, which is a preferred example of any of the first to fifth aspects, the plurality of the switching devices controlled to be driven independently of each other. In the above aspect, by activating the thermal fuse, an excessive temperature rise of the plurality of the semiconductor modules differing in phase from each other is effectively prevented.

Appendix 7: In a seventh aspect, which is the preferred example of any of the first to sixth aspects, the thermal fuse is a one-shot thermal fuse, i.e., non-return type. According to the above-described aspect, unintentional conduction can be more reliably prevented after the activation of the thermal fuse.

Appendix 8: In an eighth aspect, which is a preferred example of any of the first to sixth aspects, the thermal fuse is a resettable type. In the above aspect, if there is no abnormality in each part of the semiconductor module after the activation of the thermal fuse, the semiconductor module can be restored without replacing the thermal fuse.

Appendix 9: In a ninth aspect, which is the preferred example of any of the first to eighth aspects, the method further includes a sealing resin covering the plurality of the switching devices, the thermal fuse, the metal plate, and a portion of the external terminal. In the above aspect, since the positional relationship between the metal plate and the external terminal is fixed by the sealing resin, the electrical insulation state between the external terminal and the metal plate can be stably maintained after the activation of the thermal fuse.

Appendix 10: In a tenth aspect, which is a preferred example of the ninth aspect, a functioning temperature of the thermal fuse is less than a thermal decomposition temperature of the sealing resin. In the above aspect, the thermal fuse can activate before the sealing resin is decomposed. Therefore, unintentional conduction due to carbonization after thermal decomposition of the sealing resin can be prevented. As a result, even after the thermal fuse activates, the sealing resin not only maintains the fixed positional relation between the metal plate and the external terminal but also effectively maintains the electrical insulation.

Appendix 11: In an eleventh aspect, which is the preferred example of any of the first to tenth aspects, the apparatus further includes a temperature sensor; and a control element configured to cut off a flow of current to the plurality of the switching devices based on a temperature detected by the temperature sensor reaching a predetermined temperature lower than a functioning temperature of the thermal fuse. In the above aspect, when the control element can operate normally, it is possible to prevent an excessive temperature rise of the semiconductor module without activating the thermal fuse. In addition, even if the control element cannot operate normally due to some problem, an excessive temperature rise of the semiconductor module can be prevented by the activation of the thermal fuse.

### DESCRIPTION OF REFERENCE SIGNS

10 . . . semiconductor module,
21 . . . switching device,
22 . . . control element,
22a . . . temperature sensor,
23 . . . diode,
30 . . . lead group,
31 . . . external terminal,
32 . . . external terminal,
40 . . . sealing resin,
50 . . . wire group,
51 . . . bonding wire,
52 . . . bonding wire,
53 . . . bonding wire,
54 . . . bonding wire,
60 . . . insulating substrate,
61 . . . insulating plate,
62 . . . conductor pattern,
62a . . . metal plate,
62b . . . metal plate,
62c . . . metal plate,
62d . . . metal plate,
63 . . . conductor plate,
70 . . . thermal fuse,
90 . . . controller,
CB_U, CB_V, CB_W . . . power supply capacitor,
COM . . . common terminal,
E . . . end,
IS . . . current detecting terminal,
L1 . . . distance,
L2 . . . distance,
M . . . motor,
N_U, N_V, N_W . . . negative DC terminal,
P . . . positive DC terminal,
P1 . . . center,
R_{det} . . . current detecting resistor,
S . . . set,
U . . . output terminal,
U_{INH} . . . signal input terminal,
U_{INL} . . . signal input terminal,
U_{OUT} . . . output terminal,
V . . . output terminal,
V_{BU} . . . gate power terminal,
V_{BV} . . . gate power terminal,
V_{BW} . . . gate power terminal,
V_{CC} . . . signal power,
V_{CCH} . . . signal power terminal,
V_{CCL} . . . signal power terminal,
V_{DC} . . . DC power,
V_{INH} . . . signal input terminal,
V_{INL} . . . signal input terminal,
V_{OUT} . . . output terminal,
V_{S2U} . . . reference potential terminal,
V_{S2V} . . . reference potential terminal,
V_{S2W} . . . reference potential terminal,
V_{CC} . . . signal power supply,
W . . . output terminal,
W_{INH} . . . signal input terminal,
W_{INL} . . . signal input terminal,
W_{OUT} . . . output terminal.

What is claimed is:

1. A semiconductor module comprising:
a metal plate;
a plurality of switching devices joined to one surface of the metal plate;
a thermal fuse joined to the one surface of the metal plate; and
an external terminal electrically connected to the plurality of the switching devices by being joined to the thermal fuse.

2. The semiconductor module according to claim 1, further comprising an insulating substrate for mounting the plurality of the switching devices,
wherein the insulating substrate includes:
an insulating plate; and
a conductor pattern disposed on one surface of the insulating plate, and
wherein the conductor pattern includes the metal plate.

3. The semiconductor module according to claim 2, wherein the insulating plate is made from a resin composition.

4. The semiconductor module according to claim 3, wherein a functioning temperature of the thermal fuse is less than a thermal decomposition temperature of the resin composition.

5. The semiconductor module according to claim 1, wherein a distance between the thermal fuse and a center of a set of the plurality of the switching devices is shorter than a distance between the thermal fuse and an end of the set of the plurality of the switching devices in a longitudinal direction.

6. The semiconductor module according to claim 1, wherein the plurality of the switching devices is controlled to be driven independently of each other.

7. The semiconductor module according to claim 1, wherein the thermal fuse is a one-shot thermal fuse.

8. The semiconductor module according to claim 1, wherein the thermal fuse is a resettable thermal fuse.

9. The semiconductor module according to claim 1, further comprising a sealing resin covering the plurality of the switching devices, the thermal fuse, the metal plate, and a portion of the external terminal.

10. The semiconductor module according to claim 9, wherein a functioning temperature of the thermal fuse is less than a thermal decomposition temperature of the sealing resin.

11. The semiconductor module according to claim 1, further comprising:
a temperature sensor; and
a control element configured to cut off a flow of current to the plurality of the switching devices based on a temperature detected by the temperature sensor reaching a predetermined temperature lower than a functioning temperature of the thermal fuse.
